(19) United States
(12) Patent Application Publication
(10) Pub. No.: US 2006/0285270 A1
(43) Pub. Date: Dec. 21, 2006

(54) Cooling apparatus for electrostatic chuck

(76) Inventor: Il-Soo Lee, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/444,439

(22) Filed: Jun. 1, 2006

(30) Foreign Application Priority Data
Jun. 21, 2005 (KR) 2005-0053392

(51) Int. Cl. H01L 21/683

(52) U.S. Cl. 361/234

(57) ABSTRACT

An electrostatic chuck is disclosed with internal multi-level cooling lines or chambers circulating coolant.

### BACKGROUND OF THE INVENTION

1. Technical Field

Embodiments of the invention relate to a cooling apparatus for an electrostatic chuck adapted for use in semiconductor fabrication equipment. More particularly, embodiments of the invention relate to a cooling apparatus for an electrostatic chuck that provides an even temperature distribution throughout the electrostatic chuck by improving a structure of associated cooling lines.

This application claims the benefit of Korean Patent Application No. 10-2005-0053392, filed Jun. 21, 2005, the disclosure of which is hereby incorporated herein by reference in its entirety.

2. Discussion of Related Art

Semiconductor devices are generally fabricated through a sequence of fabrication processes, such as photolithography processes, etching processes, deposition processes, diffusion processes, and ion implantation processes. Each of these fabrication processes is typically performed in specialized process chambers. These process chambers come in a wide variety of shapes and sizes, but usually include an interior working space adapted to perform one or more related processes and some means for positioning a wafer within the interior working space.

Many specific types of process chambers adapted to the performance of etching and/or deposition processes include an electrostatic chuck as the means whereby a wafer is securely held in a desired position by an applied electrostatic force.

In addition to securing positioning the wafer, conventional electrostatic chucks are often used as electrode adapted for use in the application of Radio Frequency (RF) power to the interior working space. For example, RF power is commonly applied to the interior working space to generate a plasma in various fabrication processes.

Plasma formation, as one selected example of multiple “power” uses for a conventional electrostatic chuck, generates heat in the electrostatic chuck. Left without remedy, this generated heat would cause the temperature of the electrostatic chuck to rise above acceptable tolerances and potentially damage a wafer seated on the chuck.

More specifically, when constant RF power is applied to the electrostatic chuck in a process chamber, plasma is formed as the applied RF power reacts with a process gas in a portion of the interior working space above a wafer held on a top surface of the electrostatic chuck. Following development of the appropriate plasma, an etching process or deposition process may be applied to the wafer. A great deal of the kinetic energy generated by the plasma is converted into heat at the wafer surface, thereby raising the temperature of the wafer and the temperature of the electrostatic chuck.

Should the temperature of the electrostatic chuck rise above tolerances, the wafer seated on the top surface of the electrostatic chuck may undergo a change (e.g., thermally induced expansion) its material properties and, thereby change a critical dimension (CD) of a circuit element or component on the wafer. Any change to a critical dimension may cause a circuit or component failure and directly affect production yield of the constituent semiconductor device.

To prevent a potentially damaging temperature rise or a temperature unbalance between the wafer and electrostatic chuck, a cooling system is typically associated with the electrostatic chuck. Conventional cooling systems often directly apply a gas coolant, such as helium, to the upper surface of the electrostatic chuck or a wafer seated on the electrostatic chuck. Alternatively or additionally, a liquid and/or gas coolant is run through the body of the electrostatic chuck. This second approach of passing a coolant through the body of the electrostatic chuck is effective since conventional electrostatic chucks are often made from aluminum, a very thermally conductive material. This compares with the upper top surface of the electrostatic chuck which is typically formed from a ceramic material.

With reference to FIGS. (FIGS.) 1 and 2, a circular shaped electrostatic chuck body 1 is formed from an aluminum material and comprises an internally formed channel 2 adapted to circulate coolant (gas and/or liquid). However, as conventionally provided, channel 2 formed in body 1 is relatively short, and circulating coolant passes through body 1 relatively quickly. Such rapid exchange of coolant often leads to unpredictable cooling effects during some fabrication processes, or uneven cooling. The resulting temperature variations of a wafer seated on the conventional electrostatic chuck may cause damage to circuits and/or components formed on the wafer.

### SUMMARY OF THE INVENTION

Embodiments of the invention provide a cooling apparatus for an electrostatic chuck providing improved and better controlled cooling efficiency. Embodiments of the invention also provide a cooling apparatus for an electrostatic chuck adapted to minimize temperature variations for the electrostatic chuck.

In one embodiment, the invention provides an electrostatic chuck adapted for use in the fabrication of semiconductor devices, comprising; a body formed from a thermally conductive material and comprising an upper surface adapted to seat a wafer, a first cooling line disposed at a lower level in the body and adapted to circulate coolant, a second cooling line disposed at an upper level in the body and adapted to circulate coolant, a coolant supply pipe connected to one of the first and second cooling line and adapted to supply coolant into the body, and a coolant discharge pipe connected to one of the first and second cooling lines and adapted to discharge coolant from the body.

In another embodiment, the invention provides an electrostatic chuck adapted for use in the fabrication of semiconductor devices, comprising; a body formed from a thermally conductive material and comprising; an upper surface adapted to seat a wafer, a lower plurality of chambers disposed at a lower level in the body and adapted to circulate coolant, an upper plurality of chambers disposed at an upper level in the body and adapted to circulate coolant, a coolant supply pipe connected to one of the upper and lower pluralities of chambers and adapted to supply coolant into the body, and a coolant discharge pipe connected to one of the upper and lower pluralities of chambers and adapted to discharge coolant from the body.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a side-sectional view of a conventional electrostatic chuck;

FIG. 2 is a plan view further illustrating the cooling line through the conventional electrostatic chuck of FIG. 1;

FIG. 3 is a side-sectional view illustrating an electrostatic chuck according to an embodiment of the invention;

FIGS. 4 and 5 are plan views illustrating cooling lines in the electrostatic chuck of FIG. 3;

FIG. 6 is a side-sectional view illustrating an electrostatic chuck according to another embodiment of the invention;

FIG. 7 is a plan view illustrating a cooling line in the electrostatic chuck according to another embodiment of the invention; and

FIGS. 8 and 9 are side-sectional views illustrating an electrostatic chuck according to another embodiment of the invention.

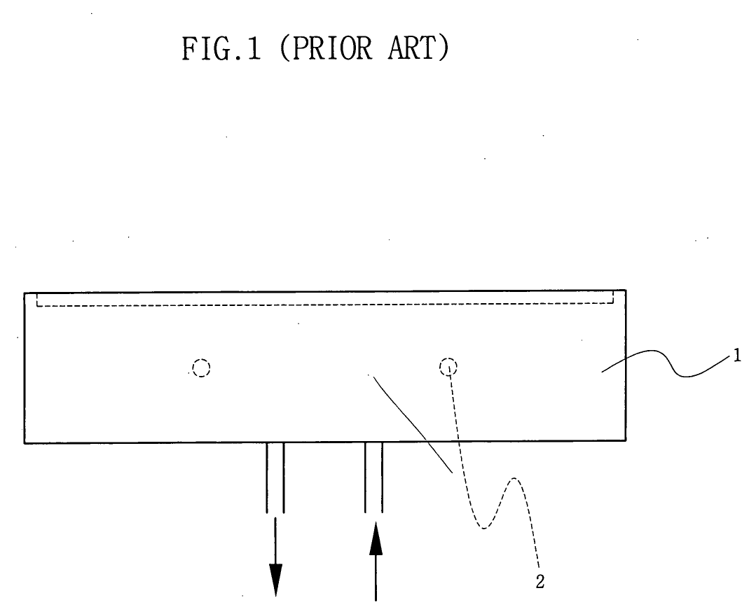

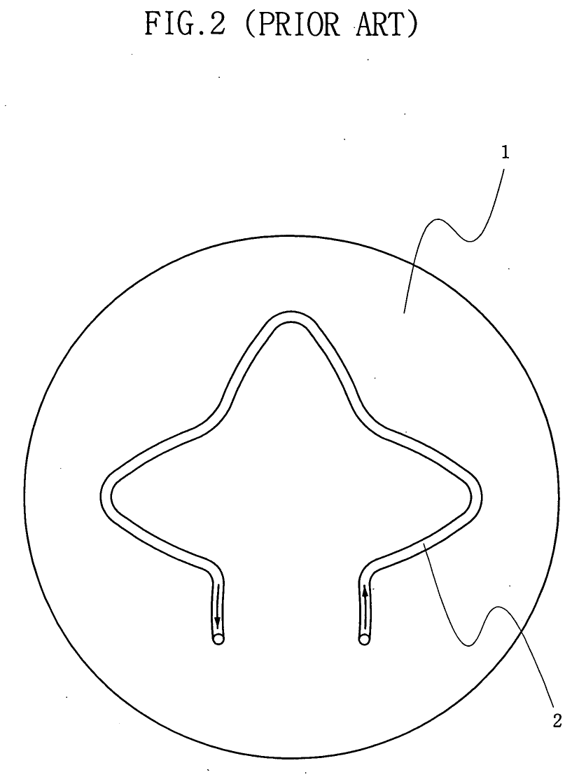

### DESCRIPTION OF EXEMPLARY EMBODIMENTS

Embodiments of the invention will now be described with reference to the accompanying drawings. The invention may, however, be embodied in many different forms and should not be construed as being limited to only the embodiments set forth herein. Rather, these embodiments are provided as teaching examples.

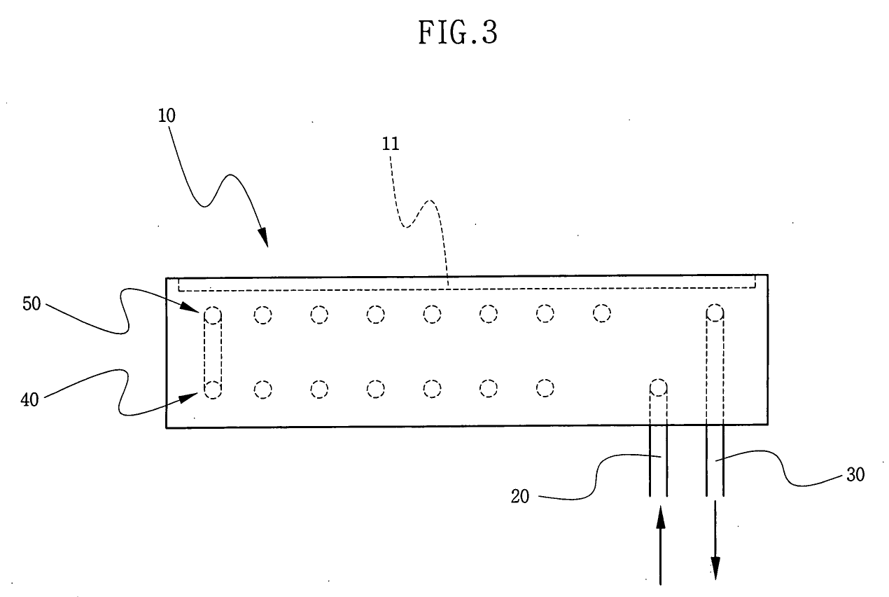

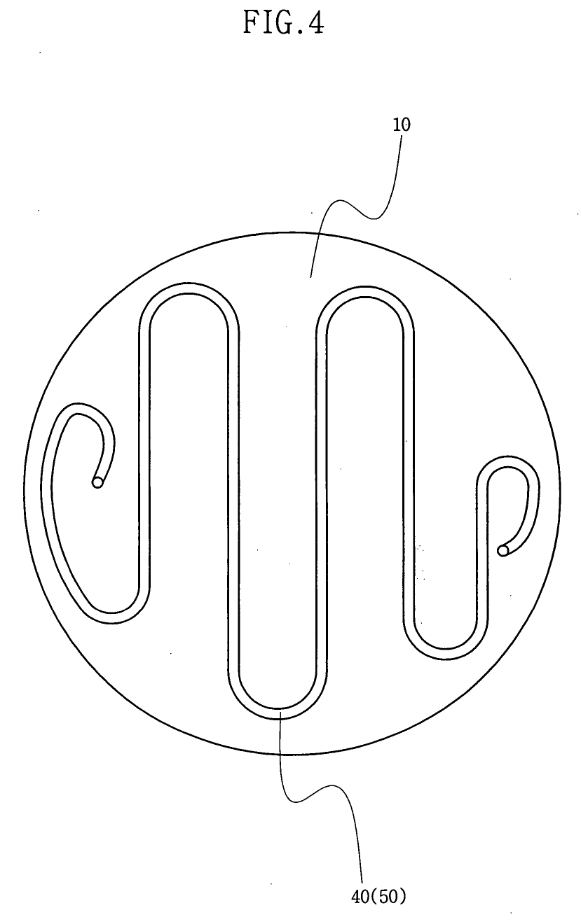

FIG. 3 is a side-sectional view illustrating an electrostatic chuck according to an embodiment of the invention. In FIG. 3, a body 10 of the electrostatic chuck may be made from an aluminum material, and a top surface of body 10 may include a plate 11 formed from a ceramic material. As further illustrated in FIG. 4, the exemplary body 10 is circular in shape

However, body 10 of the electrostatic chuck may be formed from any material and with any shape, so long as it is conducive to effective heat transfer and cooling efficiency. In addition, since body 10 will often be used as an RF electrode during certain fabrication processes, it should be formed of a conductive material having good electrical characteristics. Thus, in one embodiment, an aluminum material is preferred.

The top surface of body 10 securely seats a wafer. As a related aspect of the illustrated embodiment, a coolant gas, such as helium, may be directly applied to this top surface and a wafer seated on plate 11. In the illustrated embodiment, the top surface of the body 10 is formed from a ceramic material in such a manner so as to maximize a contact area between the helium gas and the electrostatic chuck.

Body 10 comprises a coolant supply pipe 20 adapted to supply a coolant to body 10 and a coolant discharge pipe 30 adapted to discharge the coolant circulating through body 10. Coolant supply pipe 20 and coolant discharge pipe 30 may be connected through a bottom surface of body 10.

In one embodiment, the coolant supplied to body 10 through coolant supply pipe 20 is a liquid coolant, as compared to the gas coolant directly applied to a seated wafer. This liquid coolant may be forcibly circulated by an externally provided pump.

The coolant circulates through cooling lines placed with in body 10. However, the placement and disposition of these cooling lines is highly distinct from the placement and disposition of the conventional cooling line. For example, embodiments of the invention provide for the placement of cooling lines (e.g., 40 and 50) at different levels (e.g., vertical height levels as measured from a lower reference surface for the electrostatic chuck). A relative level difference between respective cooling lines, or loops of the same cooling line, will be referred to, for example, as an “upper position” and a “lower position” within body 10. Regardless of specific layout geometry, cooling lines of predetermined diameter(s) should be uniformly placed inside body 10 at different levels.

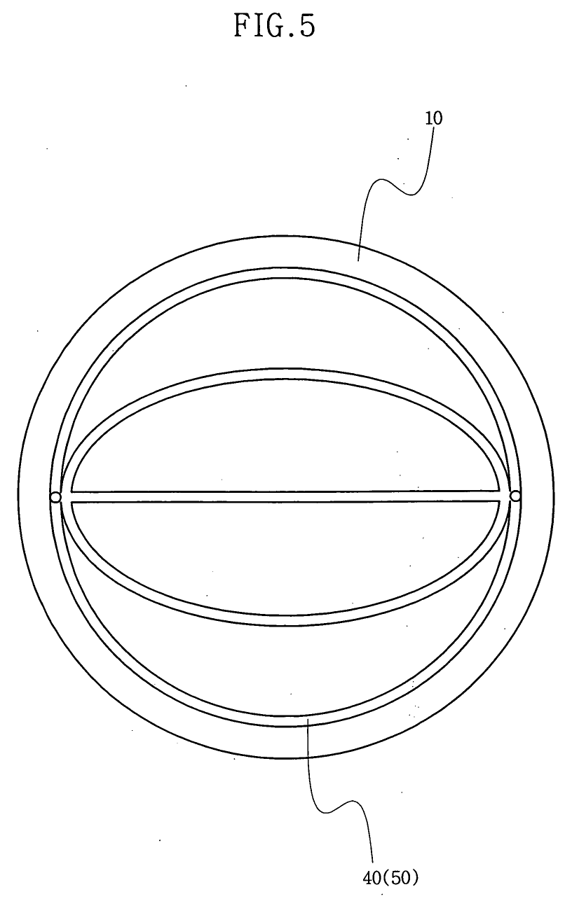

More particularly, a single respective cooling line may be placed within body 10 in zigzag pattern at an upper and/or a lower position, as illustrated on one level by FIG. 4. Alternatively, a plurality of cooling lines may be placed in a concentric pattern within body 10 at an upper and/or lower position, as illustrated on one level by FIG. 5.

With reference to FIG. 3, in another alternative, multiple loops of a cooling line may be run from a lower positioned cooling line 40 up to an upper positioned cooling line 50 at their respective ends. Either one of lower cooling line loop 40 or upper cooling line loop 50 may be connected to coolant supply pipe 20 or coolant discharge pipe 30, respectively.

In one embodiment, coolant supply pipe 20 is connected to one end of lower cooling line loop 40, lower cooling line loop 40 passes from the lower position to the upper position at the other end and becomes at one upper cooling line 50. The other end of upper cooling line 50 is connected to coolant discharge pipe 30 through the inside of body 10. However, the opposite connection between coolant supply pipe 20 and coolant discharge pipe 30 are certainly possible.

In this manner, the relative connections between coolant supply pipe 20 and coolant discharge pipe 30 with upper and lower cooling line loops 40 and 50 within body 10 determine whether a coolant first circulates through lower cooling line loop 40 or through upper cooling line loop 50. In either embodiment, the circulation of coolant through dual upper and lower cooling line loops 40 and 50 within body 10 enhances heat-transfer efficiency and generally reduces temperature variations across body 10.

In one connection arrangement, heated coolant is discharged through coolant discharge pipe 30 which is positioned adjacent to coolant supply pipe 20 having the lowest relative temperature. This juxtaposition of highest and lowest cooling temperatures further reduces thermal variation throughout body 10. As a result of all of the foregoing, a uniform temperature may be continuously maintained with respect to a wafer seated on the electrostatic chuck during a fabrication process.

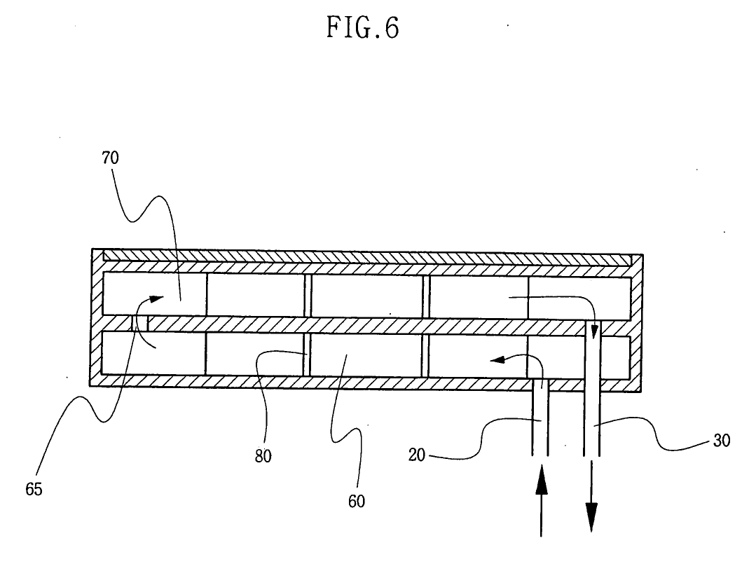

FIG. 6 is a side-sectional view illustrating an electrostatic chuck according to another embodiment of the present invention. The exemplary electrostatic chuck shown in FIG. 6 has excellent heat-transfer and cooling efficiency. Similar to the former example, the electrostatic chuck of FIG. 6 comprises a body 10 formed of a conductive material having good electrical characteristics, such as aluminum.

A coolant gas is directly applied to an upper surface of body 10 on which a wafer is seated. As before, the upper surface of body 10 may be separately formed from a ceramic material to maximize the cooling effect of the coolant gas.

Again, as before, a coolant supply pipe 20 and a coolant discharge pipe 30 are provide to communicate a liquid coolant to the electrostatic chuck.

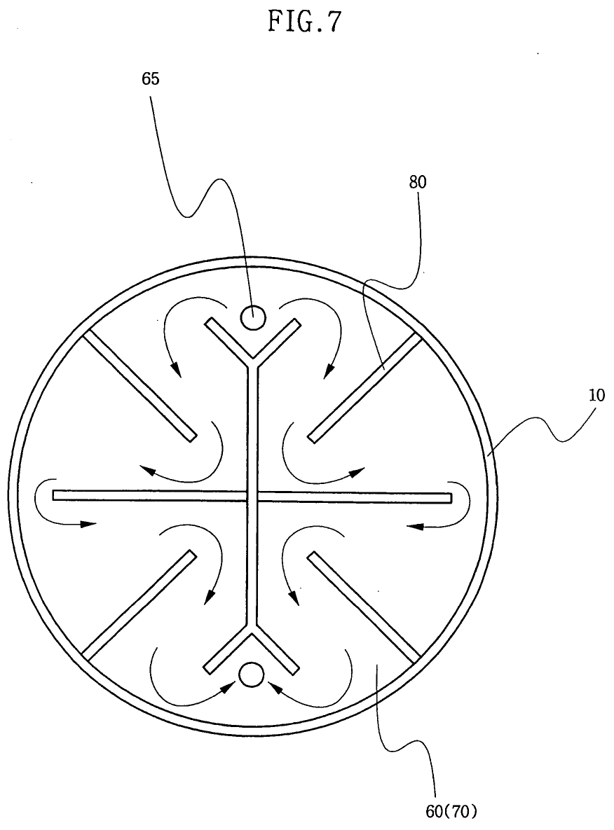

However, in the embodiment of FIG. 6, the body 10 of the electrostatic chuck comprises a plurality of hallow chambers. As further illustrated in FIG. 7, the plurality of chambers are adapted to hold and circulate the liquid coolant communicated by operation of coolant supply pipe 20 and coolant discharge pipe 30. For example, in the illustrated example of FIGS. 6 and 7, a lower plurality of chambers 60 are separated at one level by one or more partitions 80. Coolant supply pipe 20 introduces coolant into one or more of the lower plurality of chambers 60. Under pressure supplied through coolant supply pipe 20 and/or natural thermal convection, the coolant circulates around the lower plurality of chambers 60 until it passes through one or more coolant vias 65 fluidly connecting the lower plurality of chambers 60 with an upper plurality of chambers 70. The coolant then circulates through the upper plurality of chambers until passing out through coolant discharge pipe 30. The lower plurality of chambers 60 and upper plurality of chambers may have any number of specific geometric shapes and sizes, each designed to effect a particular thermal exchange facilitated by the circulating coolant. Partitions 80 may serve to define these various geometries and channel the circulating coolant.

In the illustrated example of FIGS. 6 and 7, coolant inlet via 65 connecting the upper plurality of chambers 70 with the lower plurality of chambers 60 is located on an opposite side of body 10 as compared with the connection of coolant discharge pipe 30 and coolant supply pipe 20, thereby facilitating maximum distance coolant circulation.

Here again, the upper and lower respective connections to coolant discharge pipe 30 and coolant supply pipe 20 may be reversed from those illustrated.

Here again, the coolest supply point and hottest discharge points may be grouped to minimize thermal variations within body 10.

The provision of various pluralities of chambers at multiple levels within body 10 allows coolant to circulate more evenly and slowly across body 10. Accordingly, the uneven thermal distributions that mark conventional electrostatic chucks are avoided.

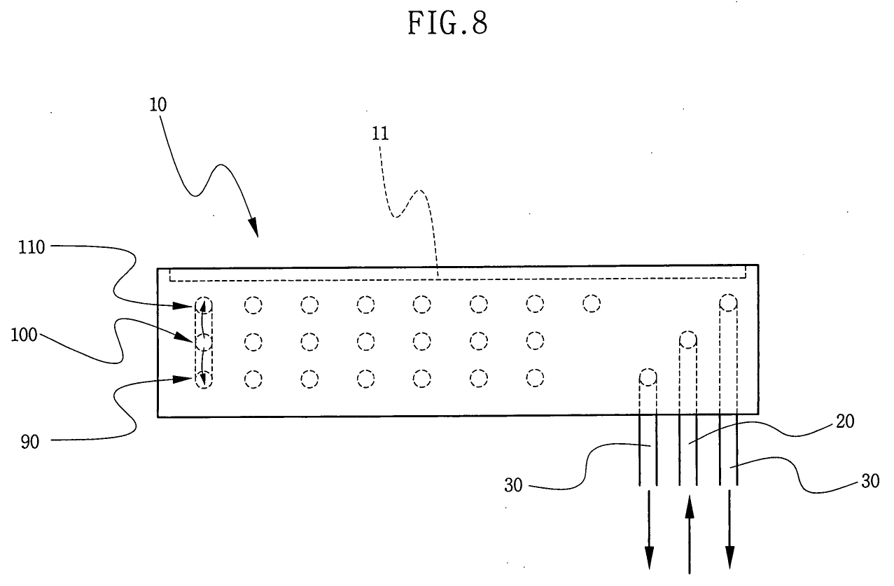

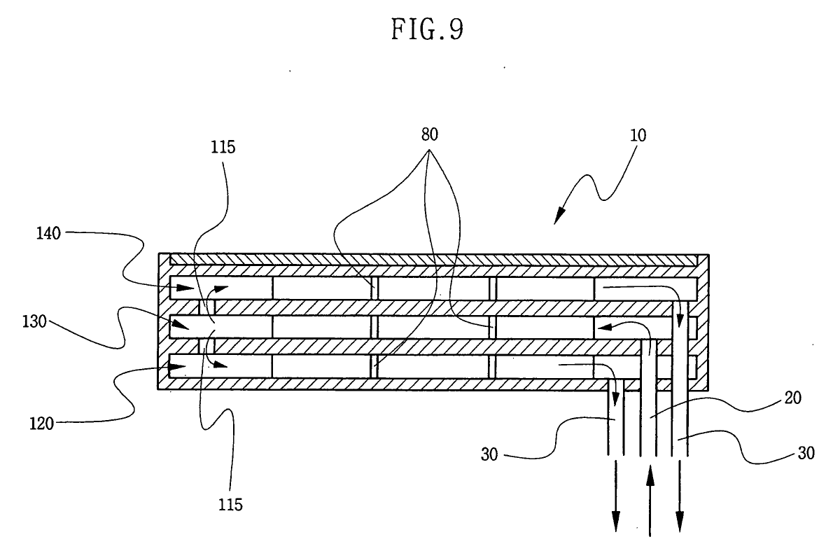

In accordance with the exemplary embodiments illustrated in FIGS. 8 and 9, additional levels (e.g., three or more) of cooling lines (90, 100, and 110), cooling line loops (90,100,110), and/or pluralities of chambers (120, 130, and 140) may be used to effect cooling of an electrostatic chuck body 10.

In the embodiment illustrated in FIG. 8, a coolant supply pipe 20 is connected to a central coolant line loop 100 at one end. The opposite end of central coolant line loop 100 is connected to upper coolant line loop 110 and lower coolant line loop 90. Each of these line loops is then respectively connected to a coolant discharge pipe 30, located proximate the connection of coolant supply pipe 20. Alternatively, each one of the foregoing line loops may be replaced with one or more separated supplied coolant lines connected between respective coolant supply pipes 20 and coolant discharge pipes 30.

In similar vein, the embodiment illustrated in FIG. 9 provides a central plurality of chambers 130 between a connected upper plurality of chambers 140 and a connected lower plurality of chambers 120. One or more coolant vias 115 allow coolant to pass between the central, upper, and lower pluralities of chambers. In the illustrated example, a single coolant supply pipe is connected at one end of the central plurality of chambers 130 opposite coolant vias 115. Supplied coolant circulates through the central plurality of chambers 120 and through coolant vias 115 to then circulate back through the upper and lower pluralities 140 and 120 to respective coolant discharge pipes 30 connected proximate the connection of coolant supply pipe 20. Alternatively, each one of the pluralities of chambers may circulate coolant supplied by a separately connected supply line 20 and discharged by a corresponding coolant discharge pipe 30.

As described in relation to the foregoing embodiments, when multiple cooling lines, cooling line loops, and/or or pluralities of cooling chambers are provided in a multi-level body of a electrostatic chuck, the coolant circulated by these elements provides improved cooling efficiency and a greater ability to manage temperature stability.

The invention has been described in the context of the foregoing exemplary embodiments. However, it will be understood by those of ordinary skill in the art that the scope of the invention is not limited to only the disclosed embodiments. On the contrary, the scope of the invention is intended to include various modifications and alternative arrangements, as defined by the claims that follow.

What is claimed is:

1. An electrostatic chuck adapted for use in the fabrication of semiconductor devices, comprising:
a body formed from a thermally conductive material and comprising an upper surface adapted to seat a wafer;
a first cooling line disposed at a lower level in the body and adapted to circulate coolant;
a second cooling line disposed at an upper level in the body and adapted to circulate coolant;
a coolant supply pipe connected to one of the first and second cooling line and adapted to supply coolant into the body; and
a coolant discharge pipe connected to one of the first and second cooling lines and adapted to discharge coolant from the body.

2. The electrostatic chuck of claim 1, wherein each one of the first and second cooling lines is disposed in a zigzag pattern within the body or each one of the first and second cooling lines comprises a plurality of cooling lines concentrically arranged within the body.

3. The electrostatic chuck of claim 1, wherein the first cooling line is connected at one end to the coolant supply pipe and at another opposite end to the second cooling line, whereby coolant passes into the electrostatic chuck, circulated through the first cooling line, and passes into the second cooling line; and
the second cooling line is connected at one end to the first cooling line and at another opposite end to the coolant discharge pipe, whereby coolant passes from the first cooling line, circulates through the second cooling line, and passes from the electrostatic chuck.

4. The electrostatic chuck of claim 3, wherein each one of the first and second cooling lines is disposed in a zigzag pattern within the body or each one of the first and second cooling lines comprises a plurality of cooling lines concentrically arranged within the body.

5. The electrostatic chuck of claim 1, wherein the second cooling line is connected at one end to the coolant supply pipe and at another opposite end to the first cooling line, whereby coolant passes into the electrostatic chuck, circulated through the second cooling line, and passes into the first cooling line; and
the first cooling line is connected at one end to the second cooling line and at another opposite end to the coolant discharge pipe, whereby coolant passes from the second cooling line, circulates through the first cooling line, and passes from the electrostatic chuck.

6. The electrostatic chuck of claim 5, wherein each one of the first and second cooling lines is disposed in a zigzag pattern within the body or each one of the first and second cooling lines comprises a plurality of cooling lines concentrically arranged within the body.

7. The electrostatic chuck of claim 1, wherein the conductive material is formed from a material containing aluminum, the upper surface is formed from a ceramic material, and the coolant is liquid.

8. The electrostatic chuck of claim 1, further comprising:
a central cooling line disposed between first and second cooling lines and connected to first and second cooling lines.

9. The electrostatic chuck of claim 8, wherein the coolant supply pipe is connected to the central cooling line at one end and to the first and second cooling lines at another opposite end, such that coolant passes from the central cooling line into the first and second cooling lines; and
wherein each one of the first and second cooling lines is connected to respective first and second coolant discharge pipes.

10. The electrostatic chuck of claim 9, wherein the first and second coolant discharge pipes are connected to the first and second cooling lines proximate the connection of the coolant supply pipe to the central cooling line.

11. An electrostatic chuck adapted for use in the fabrication of semiconductor devices, comprising:
a body formed from a thermally conductive material and comprising:
an upper surface adapted to seat a wafer;
a lower plurality of chambers disposed at a lower level in the body and adapted to circulate coolant;
an upper plurality of chambers disposed at an upper level in the body and adapted to circulate coolant;
a coolant supply pipe connected to one of the upper and lower pluralities of chambers and adapted to supply coolant into the body; and
a coolant discharge pipe connected to one of the upper and lower pluralities of chambers and adapted to discharge coolant from the body.

12. The electrostatic chuck of claim 11, further comprising:
one or more coolant vias disposed between the upper and lower pluralities of chambers and adapted to pass coolant.

13. The electrostatic chuck of claim 12, wherein the coolant supply pipe is connected to the lower plurality of chambers and the coolant discharge pipe is connected to the upper plurality of chambers.

14. The electrostatic chuck of claim 12, wherein the coolant supply pipe is connected to the upper plurality of chambers and the coolant discharge pipe is connected to the lower plurality of chambers.

15. The electrostatic chuck of claim 11, further comprising:
a central plurality of chambers disposed between the upper and lower pluralities of chambers; and,
at least one coolant via disposed between the central, upper, and lower pluralities of chambers and adapted to pass coolant.

16. The electrostatic chuck of claim 15, wherein the coolant supply pipe is connected to one end of the central plurality of chambers and at least one coolant via is disposed at another opposite end of the central plurality of chambers, such that coolant passes from the central plurality of chambers into the upper and lower pluralities of chambers; and
wherein each one of the upper and lower pluralities of chambers is connected to respective first and second coolant discharge pipes.

17. The electrostatic chuck of claim 16, wherein the first and second coolant discharge pipes are connected to the upper and lower pluralities of chambers proximate the connection of the coolant supply pipe to the central plurality of chambers.

18. The electrostatic chuck of claim 11, wherein the conductive material is formed from a material containing aluminum, the upper surface is formed from a ceramic material, and the coolant is liquid.
